(19) United States
(12) Patent Application Publication
(10) Pub. No.: US 2025/0261410 A1
(43) Pub. Date: Aug. 14, 2025

(54) Ferroelectric Transistor, Memory Circuitry Comprising Ferroelectric Transistors, And Method Used In Forming Memory Circuitry Comprising Memory Cells That Individually Comprise A Horizontal Ferroelectric Transistor

(71) Applicant: Micron Technology, Inc., Boise, ID (US)

(72) Inventors: Kamal M. Karda, Boise, ID (US); Durai Vishak Nirmal Ramaswamy, Boise, ID (US); Haitao Liu, Boise, ID (US); Karthik Sarpatwari, Boise, ID (US)

(73) Assignee: Micron Technology, Inc., Boise, ID (US)

(21) Appl. No.: 19/007,854

(22) Filed: Jan. 2, 2025

Related U.S. Application Data
(60) Provisional application No. 63/551,319, filed on Feb. 8, 2024.

(51) Int. Cl. H10D 30/69; H10B 51/10; H10B 51/30; H10D 30/01

(52) U.S. Cl. CPC H10D 30/701; H10B 51/10; H10B 51/30; H10D 30/0415

(57) ABSTRACT

A ferroelectric transistor comprises two source/drain regions having a channel region horizontally there-between. The channel region has opposing front and back sides along a horizontal current-flow direction through the channel region. A front gate is on the front side of the channel region. A front-gate insulator is horizontally between the front gate and the front side of the channel region. The front-gate insulator comprises a dielectric material and a ferroelectric material that are each directly against the front gate. More of the ferroelectric material is directly against the front gate than is the dielectric material. Other embodiments, including methods, are disclosed.

### TECHNICAL FIELD

Embodiments disclosed herein pertain to ferroelectric transistors, to memory circuitry comprising ferroelectric transistors, and to methods used in forming memory circuitry comprising memory cells that individually comprise a horizontal ferroelectric transistor.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, sense lines, or data/sense lines) and access lines (which may also be referred to as wordlines). The digitlines may conductively interconnect memory cells along columns of the array, and the access lines may conductively interconnect memory cells along rows of the array.

Memory cells may be volatile or nonvolatile. Nonvolatile memory cells can store data for extended periods of time including when the computer is turned off. Volatile memory dissipates and therefore requires being refreshed/rewritten, in many instances multiple times per second. Regardless, memory cells are configured to retain or store memory in at least two different selectable states. In a binary system, the states are considered as either a “0” or a “1”. In other systems, at least some individual memory cells may be configured to store more than two levels or states of information.

Ferroelectric field effect transistors (FeFET) may be used as memory cells. Specifically, the FeFETs may have two selectable memory states corresponding to two different polarization modes of ferroelectric material within the FeFETS. The different polarization modes may be characterized by, for example, different threshold voltages (Vt) or by different channel conductivities for a selected operating voltage. The ferroelectric polarization mode of a FeFET may remain in the absence of power (at least for a measurable duration).

One type of ferroelectric transistor is a metal-ferroelectric-metal-insulator-semiconductor (MFMIS) transistor. Such has a gate dielectric (insulator, I) between metal (M) and semiconductor material(S). Such also has ferroelectric (F) material over the metal, and has a gate (typically comprising metal, M) over the ferroelectric material. In operation, an electric field across the ferroelectric material is used to switch the ferroelectric material from one polarization mode to another. The ferroelectric transistor comprises a pair of source/drain regions, and a channel region between the source/drain regions. Conductivity across the channel region is influenced by the polarization mode of the ferroelectric material. Another type of ferroelectric transistor is metal-ferroelectric-insulator-semiconductor (MFIS) in which ferroelectric material directly touches the insulator (i.e., in which there is no intervening metal between the ferroelectric material and the insulator).

It is desired to develop ferroelectric transistors which are scalable to ever-increasing levels of integration.

### BRIEF DESCRIPTION OF THE DRAWINGS

FIGS. 1-7 are diagrammatic cross-sectional views of portions of constructions in accordance with some embodiments of the invention.

FIGS. 8-21 are diagrammatic cross-sectional views of portions of a construction in process in accordance with an embodiment of the invention.

### DETAILED DESCRIPTION OF EXAMPLE EMBODIMENTS

Embodiments of the invention comprise ferroelectric transistors, memory circuitry so comprising, and methods used in forming memory circuitry so comprising.

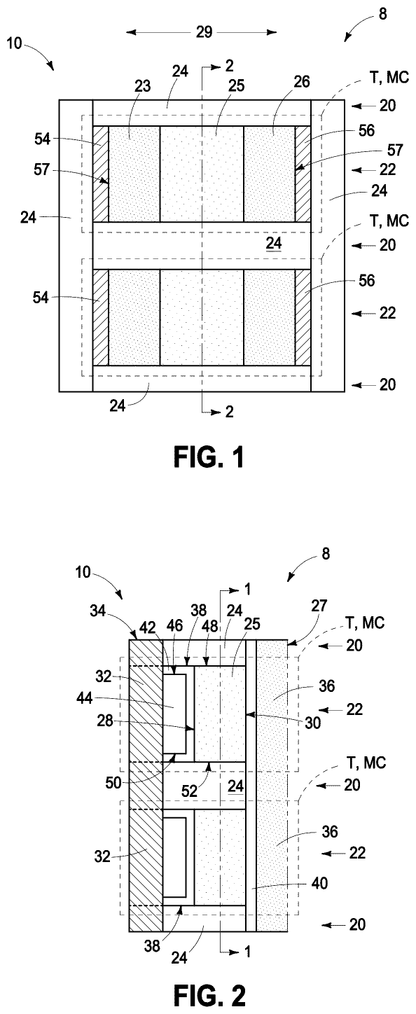

A first example embodiment of such memory circuitry is described with reference to FIGS. 1 and 2. Such depicts a construction 8 comprising memory circuitry 10 comprising individual ferroelectric transistors T that comprise individual memory cells MC (only two of each being shown). Construction 8 comprises vertically-alternating insulative tiers 20 (comprising insulative material 24; e.g., silicon dioxide) and memory-cell tiers 22. Only a few such tiers are shown, with construction 8 likely comprising dozens, hundreds, etc. more such tiers, ferroelectric transistors, and memory cells. Tiers 20 are shown as being thicker than tiers 22, although such may be reversed, or such may be of the same thickness. Individual ferroelectric transistors T comprise a first source/drain region 23 and a second source/drain regions 26 (two source/drain regions) (e.g., each being heavily-doped semiconductor material [e.g., silicon] to be conductive) having a channel region 25 horizontally there-between (e.g., undoped or lightly-doped semiconductor material of opposite type to that of regions 23, 26). Channel region 25 has opposing front and back sides 28 and 30, respectively, along a horizontal current-flow direction 29 through channel region 25. Horizontal current-flow direction 29 in some embodiments is referred to as first direction 29. Example insulative material 24 is shown extending through tiers 20 and 22 on opposing first-direction lateral sides of transistors T.

A front gate 32 (e.g., comprising conductive metal material) is on front side 28 of channel region 25. Front gate 32 comprises part of one of a plurality of conductive vertical front access lines 34 (one being shown in FIG. 2) that individually directly electrically couple together multiple front gates 32 of different ones of ferroelectric transistors T that are in different ones of memory-cell tiers 22. In one embodiment, a back gate 36 is on back side 30 of channel region 25. Back gate 36 comprises part of one of a plurality of conductive vertical back lines 27 (one being shown in FIG. 2; e.g., p-type conductively-doped semiconductive material and/or metal) that individually directly electrically couple together multiple back gates 36 of the different ones of ferroelectric transistors T that are in the different ones of memory-cell tiers 22. In one embodiment, a back-gate insulator 40 (e.g., comprising silicon dioxide and/or silicon nitride) is horizontally between back gate 36 and back side 30 of channel region 25. Back gates 36/back lines 27 may be biased to any suitable potential (zero voltage, positive voltage, negative voltage), for example to reduce floating body effect.

A front-gate insulator 38 is horizontally between front gate 32 and front side 28 of channel region 25. Front-gate insulator 38 comprises a dielectric material 42 and a ferroelectric material 44. Dielectric material 42 may comprise any suitable composition(s), for example one or more of silicon dioxide, silicon nitride, aluminum oxide, hafnium oxide, zirconium oxide, etc. Ferroelectric material 44 may comprise any suitable composition(s), for example one or more materials selected from the group consisting of transition metal oxide, zirconium, zirconium oxide, hafnium, hafnium oxide, lead zirconium titanate, tantalum oxide, and barium strontium titanate, and having dopant therein which comprises one or more of silicon, aluminum, lanthanum, yttrium, erbium, calcium, magnesium, strontium, and a rare earth element.

In one embodiment, front-gate insulator 38 comprises at least one of (a) and (b), where:
(a): dielectric material 42 is directly against front side 28 of channel region 25, ferroelectric material 44 is directly against front gate 32, ferroelectric material 44 has a top 46 that is below a top 48 of channel region 25, ferroelectric material 44 has a bottom 50 that is above a bottom 52 of channel region 25, and dielectric material 42 extends continuously from front side 28 of channel region 25 to be both directly against top 46 and bottom 50 of ferroelectric material 44; and
(b): dielectric material 42 is directly against front side 28 of channel region 25, dielectric material 42 and ferroelectric material 44 are each directly against front gate 32, and more of ferroelectric material 44 is directly against front gate 32 than is dielectric material 42.

In one embodiment, front-gate insulator 38 comprises the (a). In one such embodiment, ferroelectric material 44 is not directly against front side 28 of channel region 25. In another one such embodiment, dielectric material 42 is directly against front gate 32. In another one such embodiment, dielectric material 42 does not extend upwardly or downwardly into immediately-vertically-adjacent of insulative tiers 20 (there being no other tier 20 between those that are immediately-vertically-adjacent one another) and has a C-like shape (including a mirror image thereof) in a vertical cross-section (e.g., that of FIG. 2). The depicted example C-like shape has the “C” having three straight segments. Of course, such could be other three straight segments including, for example, being continuously-curved and of constant or varying radius or arc, more than three straight segments, a combination of straight segments and curved segments, be all curved segments, etc. as long as a capital general C-like shape (or mirror image thereof) results in certain embodiments.

In one embodiment, front-gate insulator 38 comprises the (b). In one such embodiment, ferroelectric material 44 is not directly against front side 28 of channel region 25. In one such embodiment, dielectric material has a C-like shape in a vertical cross-section. In one embodiment, front-gate insulator 38 comprises the (a) and the (b).

In one embodiment, memory circuitry 10 comprises horizontal digitlines (e.g., 54 and/or 56) in individual of memory-cell tiers 22. Individual of one of two source/drain regions 23 or 26 of individual ferroelectric transistors T that are in the same memory-cell tier 22 are directly electrically coupled to one of the horizontal digitlines. In one such embodiment, the one horizontal digitline (e.g., 54 or 56) is directly against a lateral-side surface 57 of the individual one of two source/drain regions 23 or 26.

In one embodiment, memory circuitry 8 comprises horizontal first and second comparative digitlines 54 and 56 in individual memory-cell tiers 22, with individual first source/drain regions 23 of individual ferroelectric transistors T that are in the same memory-cell tier being directly electrically coupled to one of horizontal first comparative digitlines 54 and with individual of second source/drain regions 26 being directly electrically coupled to one horizontal second comparative digitlines 56. In one embodiment, the one horizontal first comparative digitline 54 is directly against lateral-side surface 57 of individual first source/drain regions 23 and the one horizontal second comparative digitline 56 is directly against lateral-side surface 57 of individual second source/drain regions 26. Regardless, comparative digitlines 54 and 56 may be one of “true” and the other “complementary”, for example that may be coupled with driver circuitry and reference circuitry, respectively, (or other circuitry) and for example as disclosed in our U.S. Patent Application Publication No. 2023/0041784. Analogously, conductive vertical front access lines 34 and/or conductive vertical back lines 27 may be coupled with other driver circuitry (or other circuitry), also for example as disclosed in our U.S. Patent Application Publication No. 2023/0041784.

Any other attribute(s) or aspect(s) as shown and/or described herein with respect to other embodiments may be used in the embodiments shown and described with reference to the above embodiments.

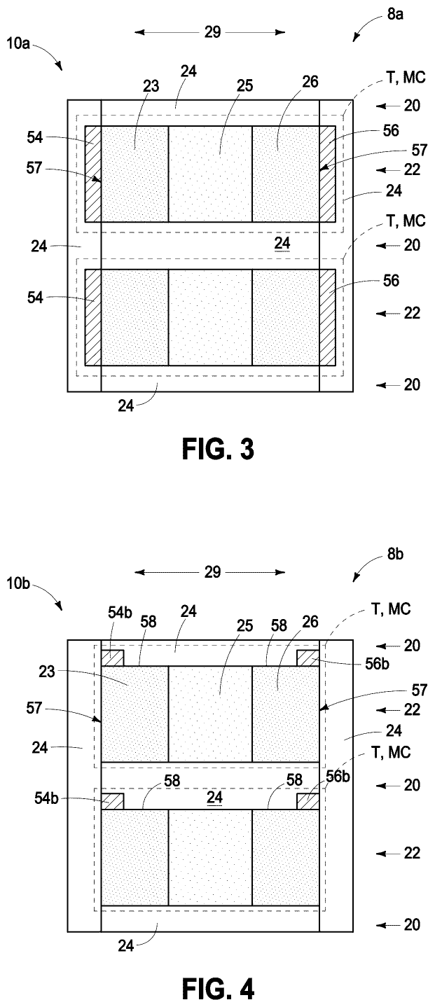

The example above embodiments show horizontal digitlines 54 and 56 as being laterally-displaced from the insulative material 24 that extends through tiers 20 and 22 on opposing first-direction lateral sides of transistors T. FIG. 3 shows an alternate example construction 8a comprising memory circuitry 10a wherein horizontal digitlines 54 and 56 are embedded within such insulative material 24. Like numerals from the above-described embodiments have been used where appropriate, with some construction differences being indicated with the suffix “a” or with different numerals. Any other attribute(s) or aspect(s) as shown and/or described herein with respect to other embodiments may be used.

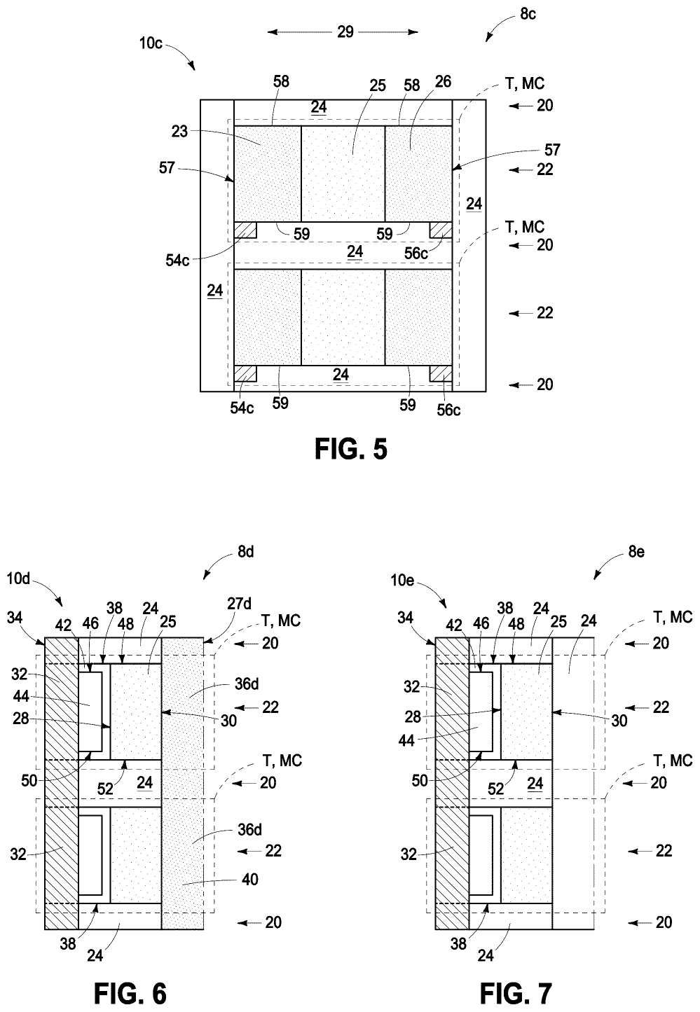

The example above embodiments show horizontal digitlines 54 and 56 as being directly against a lateral-side surface 57 of the individual one of two source/drain regions 23 or 26. Alternately, such digitlines 54b, 56b or 54c, 56c of constructions 8b and 8c, respectively, of memory circuitry 10b and 10c, respectively, may be directly against a top surface 58 or a bottom surface 59 of individual source/drain regions 23 and 26, as shown in FIGS. 4 and 5, respectively. Like numerals from the above-described embodiments have been used where appropriate, with some construction differences being indicated with the suffix “b” or the suffix “c” or with different numerals. Any other attribute(s) or aspect(s) as shown and/or described herein with respect to other embodiments may be used.

The example first-described embodiment shows back-gate insulator 40 as being horizontally between back gate 36 and back side 30 of channel region 25 such that back gate 36 is not directly against channel region 25. An alternate construction 8d comprising memory circuitry 10d is shown in FIG. 6 wherein back gate 36d of conductive vertical back line 27d is directly against back side 30 of channel region 25 (e.g., there being no back-gate insulator 40). Like numerals from the above-described embodiments have been used where appropriate, with some construction differences being indicated with the suffix “d” or with different numerals. Any other attribute(s) or aspect(s) as shown and/or described herein with respect to other embodiments may be used.

FIG. 7 shows an alternate example construction 8e comprising memory circuitry 10e. Such does not have a back gate 36* (not shown) or a back line 27* (not shown), with example insulative material 24 being directly against channel-region back side 30 (an * being used as a suffix to be inclusive of all such same-numerically-designated structures or portions thereof that may or may not have other suffixes).

Embodiments of the invention encompass a ferroelectric transistor regardless of whether comprising vertically-alternating insulative and memory-cell tiers. In one such embodiment, such a ferroelectric transistor (e.g., T) comprises two source/drain regions (e.g., 23, 26) having a channel region (e.g., 25) horizontally there-between. The channel region has opposing front and back sides (e.g., 28 and 30, respectively) along a horizontal current-flow direction (e.g., 29) through the channel region. A front gate (e.g., 32) is on the front side of the channel region and a back gate (e.g., 36) is on the back side of the channel region. A front-gate insulator (e.g., 38) is horizontally between the front gate and the front side of the channel region. The front-gate insulator comprises a dielectric material (e.g., 42) and a ferroelectric material (e.g., 44) and at least one of the (a) and the (b) as described above. Any other attribute(s) or aspect(s) as shown and/or described herein with respect to other embodiments may be used.

In another such embodiment, a ferroelectric transistor (e.g., T) comprises two source/drain regions (e.g., 23 and 26) having a channel region (e.g., 25) horizontally there-between. The channel region has opposing front and back sides (e.g., 28 and 30, respectively) along a horizontal current-flow direction (e.g., 29) through the channel region. A front gate (e.g., 32) is on the front side of the channel region. A front-gate insulator (e.g., 38) is horizontally between the front gate and the front side of the channel region. The front-gate insulator comprises a dielectric material (e.g., 42) and a ferroelectric material (e.g., 44) that are each directly against the front gate. More of the ferroelectric material is directly against the front gate than is the dielectric material (regardless of presence of a back gate). Any other attribute(s) or aspect(s) as shown and/or described herein with respect to other embodiments may be used.

In one embodiment, memory circuitry (e.g., 10*) comprises vertically-alternating insulative tiers (e.g., 20) and memory-cell tiers (e.g., 22). The memory-cell tiers comprise memory cells (e.g., MC) that individually comprise a ferroelectric transistor (e.g., T) comprising two source/drain regions (e.g., 23, 26) having a channel region (e.g., 25) horizontally there-between. The channel region has opposing front and back sides (e.g., 28 and 30, respectively) along a horizontal current-flow direction (e.g., 29) through the channel region. A front gate (e.g., 32) is on the front side of the channel region. The front gate comprises part of one of a plurality of conductive vertical front access lines (e.g., 34) that individually directly electrically couple together multiple of the front gates of different ones of the ferroelectric transistors that are in different ones of the memory-cell tiers. A front-gate insulator (e.g., 38) is horizontally between the front gate and the front side of the channel region. The front-gate insulator comprises a dielectric material (e.g., 42) and a ferroelectric material (e.g., 44) that are each directly against the front gate. More of the ferroelectric material is directly against the front gate than is the dielectric material (regardless of presence of a conductive back line). Any other attribute(s) or aspect(s) as shown and/or described herein with respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

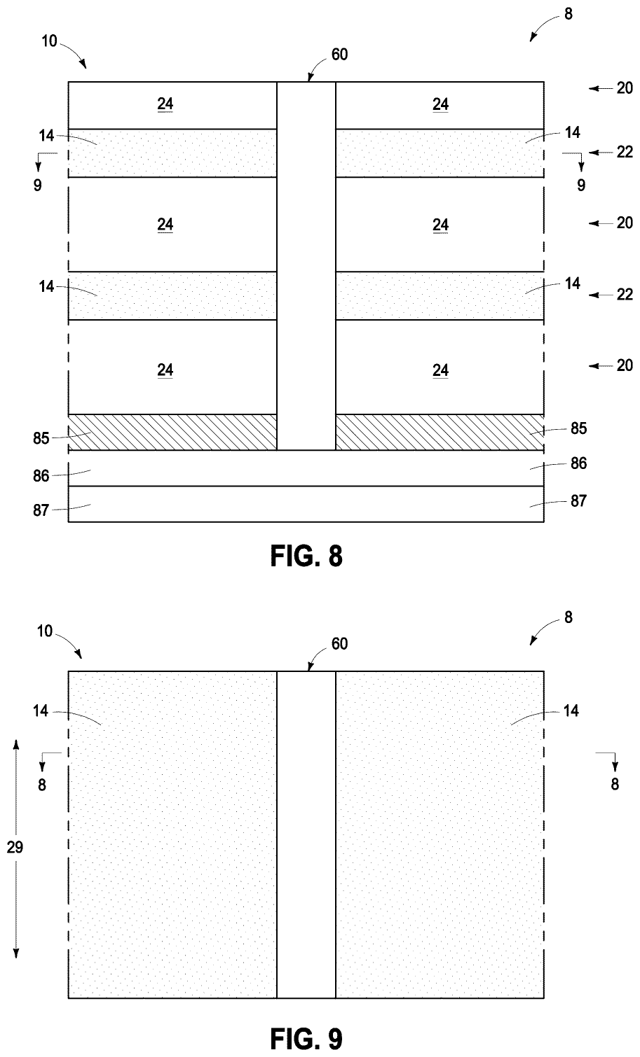

FIGS. 8-21 by way of example sequentially show a predecessor construction 8 in example methods used in forming memory circuitry, with such circuitry comprising memory cells that individually comprise a transistor and a capacitor.

Referring to FIGS. 8 and 9, vertically-alternating insulative tiers 20 and memory-cell tiers 22 have been formed atop a substrate comprising conductive material 85, that is atop insulator material 86, and that is atop a semiconductor substrate 87. Memory-cell tiers 22 ideally comprise semiconductor material 14 (e.g., monocrystalline or polycrystalline silicon) at a desired finished-composition of an eventual channel region 25 (e.g., undoped semiconductor material or lightly-doped semiconductor material of opposite p-type or n-type to the conductivity type of eventual source/drain regions 23 and 26). An insulator wall 60 (e.g., comprising silicon dioxide and/or silicon nitride) extends through insulative tiers 20 and memory-cell tiers 22. Insulator wall 60 is horizontally-elongated along a first direction 29.

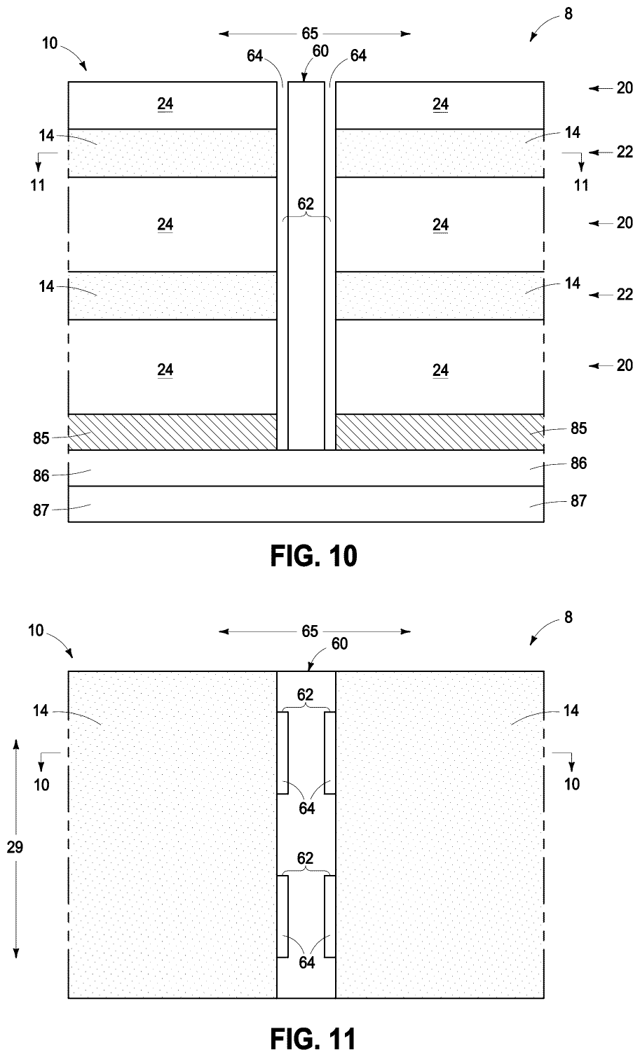

Referring to FIGS. 10 and 11, pairs 62 of first openings 64 have been formed and that extend vertically-through insulator wall 60 and are spaced from one another along first direction 29. Individual of first openings 64 in individual pairs 62 are spaced from one another in a second direction 65 that is orthogonal to first direction 29.

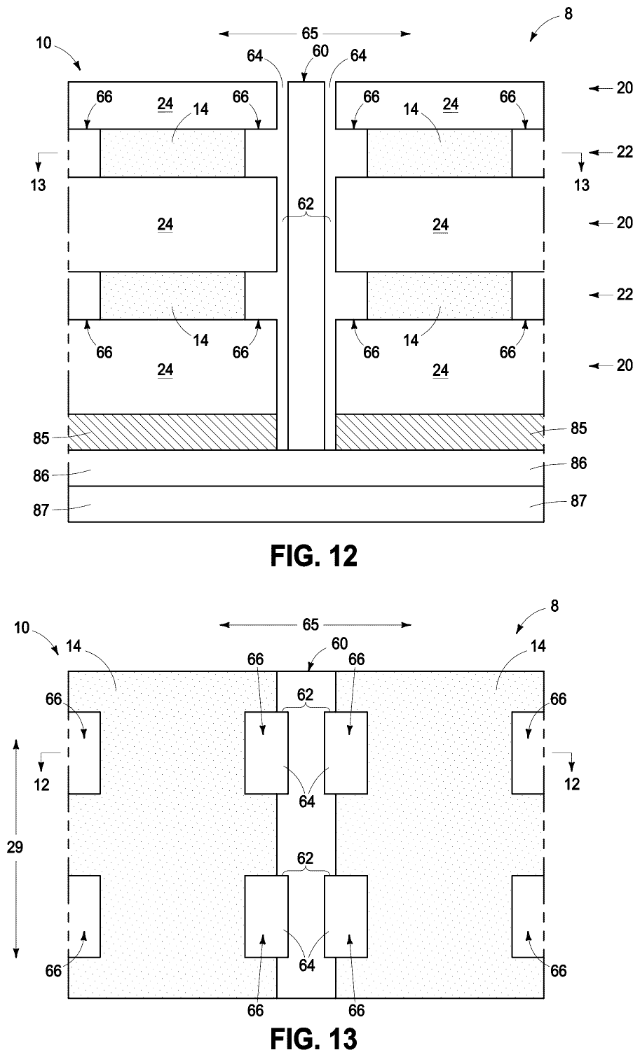

Referring to FIGS. 12 and 13, through individual first openings 64, semiconductor material 14 has been laterally recessed in second direction 65 (e.g., by isotropic etching) in individual memory-cell tiers 22 selectively relative to insulative tiers 20 to form cavities 66. Semiconductor material 14 will comprise a channel region 25 of individual horizontal ferroelectric transistors T being formed.

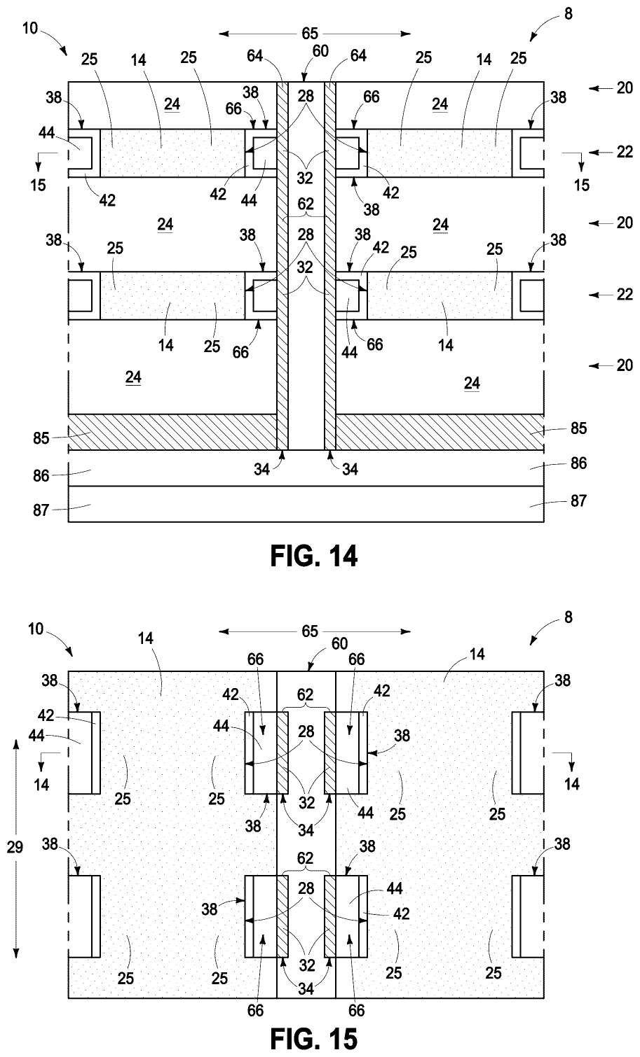

Referring to FIGS. 14 and 15, cavities 66 have been lined with dielectric material 42 to vertically-narrow (at least vertically) cavities 66. This has been followed by forming ferroelectric material 44 within vertically-narrowed cavities 66 (e.g., forming front-gate insulator 38 that may have any of the above-described attributes thereof). Thereafter, a conductive front access line 34 has been formed in individual first openings 64. Conductive front access line 34 comprises a front gate 32 on a front side 28 of channel region 25 of individual horizontal ferroelectric transistors that are being formed and directly electrically couples together multiple of front gates 32 of different ones of the horizontal ferroelectric transistors that are in different ones of memory-cell tiers 22. Dielectric and ferroelectric materials 42 and 44 are horizontally between front side 28 of channel region 35 and front gate 32.

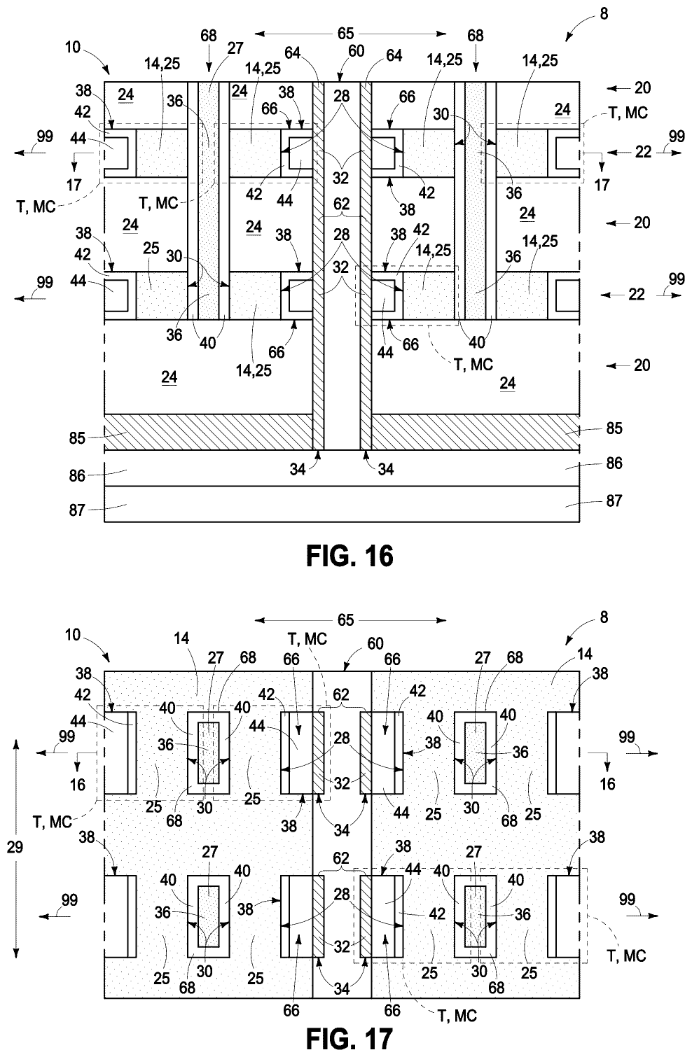

In one such embodiment and referring to FIGS. 16 and 17, second openings 68 have been formed vertically-through vertically-alternating insulative tiers 20 and memory-cell tiers 22. Second openings 68 are spaced relative one another along first direction 29 and are individually linearly-aligned in second direction 65 with individual pairs 62 of first openings 64 (e.g., along lines 99). Thereafter, a conductive back line 27 has been formed in individual second openings 68. Conductive back line 27 comprises a back gate 36 on a back side 30 of channel region 25 of the individual horizontal ferroelectric transistors T that are being formed and directly electrically couples together multiple of back gates 36 of different ones of the horizontal ferroelectric transistors T that are in different ones of memory-cell tiers 22. Back-gate insulator 40 may be formed prior to forming conductive back lines 27, or such may not be so formed. Regardless, in one embodiment and as shown, second direction 65 may be considered as a horizontal orthogonal direction 65 that is orthogonal to horizontal current-flow direction 29, with back gate 36 and individual of conductive vertical back lines 27 being shared by two memory cells MC that are being formed and that are immediately-adjacent one another in horizontal orthogonal direction 65 in the same memory-cell tier 22 (regardless of presence of back-gate insulator 40).

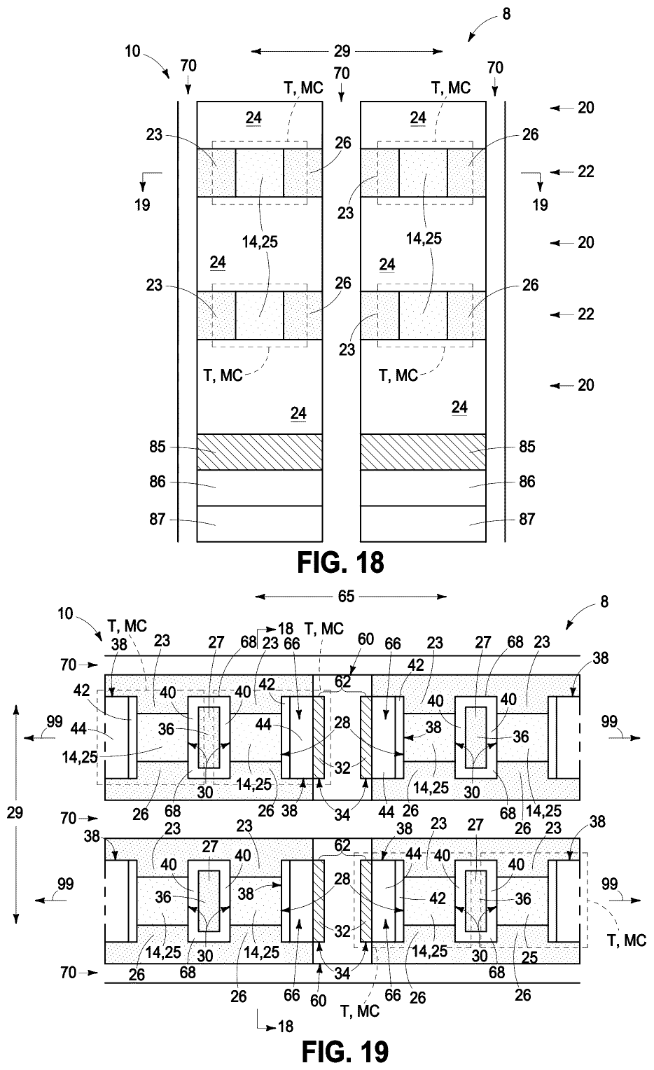

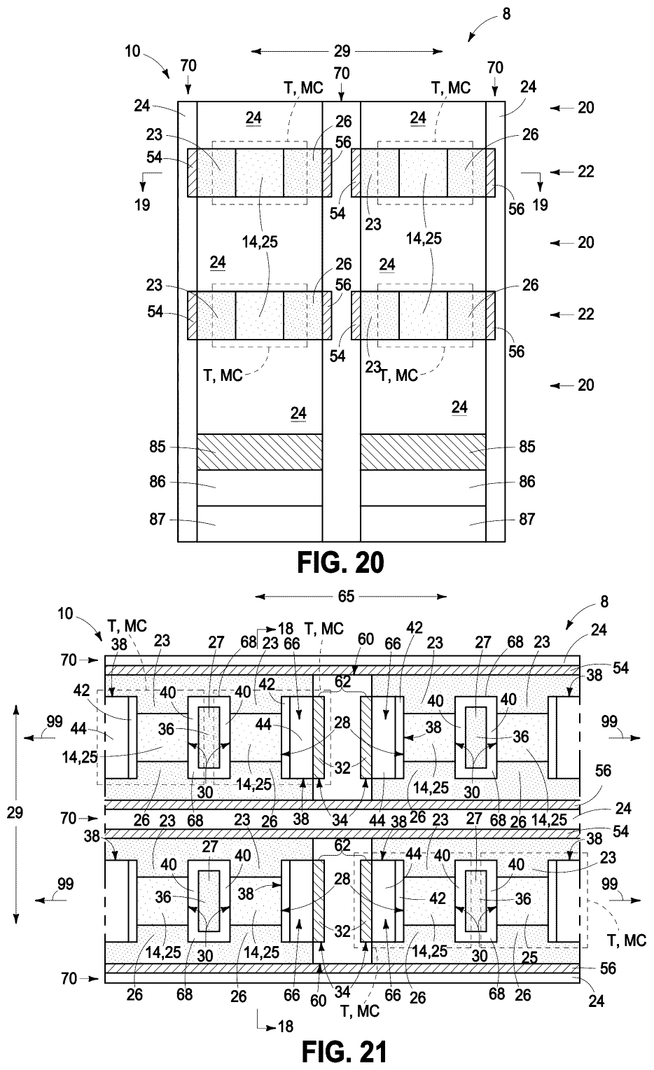

In one additional such embodiment and referring to FIGS. 18 and 19, digitline trenches 70 (trenches in which digitlines will be formed) have been formed. Thereafter, semiconductor material 14 has been formed to comprise two source/drain regions 23 and 26 having channel region 25 horizontally there-between along first direction 29 (e.g., by gas-phase conductive-diffusion-doping of regions 23 and 26 with conductivity-increasing dopant through digitline trenches 70). Referring to FIGS. 20 and 21, horizontal digitlines 54 and 56 have been formed in digitline trenches 70 in individual memory-cell tiers 22, with individual of one of two source/drain regions 23, 26 of individual ferroelectric transistors T that are in the same memory-cell tier being directly electrically coupled to one of horizontal digitlines 54 and 56 (e.g., to form the example embodiment of FIG. 3). As but one example of forming digitlines 54 and 56, such may be selectively grown from source/drain regions 23 and 26. Such selective growth may also grow across insulator wall 60, particularly where such is laterally-thinner than vertical-thickness of insulative tiers 20 to preclude sufficient vertical growth that would result in vertical shorting of immediately-vertically-adjacent digitlines. Source/drain regions 23 and 26 may optionally be laterally recessed in second/orthogonal direction 65 prior to such selective growth (not shown) to produce a construction analogous to that of FIG. 1. Regardless, digitlines 54 and 56 may be formed before or after forming conductive lines 34 and/or 27. Digitlines 54 and 56 may comprise horizontal first and second comparative digitlines as described above. Further, the digitlines may be fabricated to have any of the constructions of FIGS. 4 and/or 5. Remaining volume of digitline trenches 70 has been filled with insulative material 24.

Any other attribute(s) or aspect(s) as shown and/or described herein with respect to other embodiments may be used.

Ideally and as shown, ferroelectric transistors T are MFIS although less ideally could be MFMIS.

Some embodiments of the invention may improve programming speed in erase/writing “0” due to presence of a back gate due to likely elimination of floating body effect. Further, use of a back gate may enable additional or different select schemes for addressing the memory circuitry. Some method embodiments may enable isolation of ferroelectric material 44 in a largely self-aligned manner (e.g., from first openings 64). Further, some method embodiments may enable use of higher temperature anneals to achieve larger grains in regions 23, 25, and 26, which may increase conductivity and/or performance.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials- components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a ferroelectric transistor comprises two source/drain regions having a channel region horizontally there-between. The channel region has opposing front and back sides along a horizontal current-flow direction through the channel region. A front gate is on the front side of the channel region and a back gate is on the back side of the channel region. A front-gate insulator is horizontally between the front gate and the front side of the channel region. The front-gate insulator comprises a dielectric material and a ferroelectric material and at least one of (a) and (b), where: (a): the dielectric material is directly against the front side of the channel region, the ferroelectric material is directly against the front gate, the ferroelectric material has a top that is below a top of the channel region, the ferroelectric material has a bottom that is above a bottom of the channel region, and the dielectric material extends continuously from the front side of the channel region to be both directly against the top and the bottom of the ferroelectric material; and (b): the dielectric material is directly against the front side of the channel region, the dielectric material and the ferroelectric material are each directly against the front gate, and more of the ferroelectric material is directly against the front gate than is the dielectric material.

In some embodiments, memory circuitry comprises vertically-alternating insulative tiers and memory-cell tiers. The memory-cell tiers comprise memory cells that individually comprise a ferroelectric transistor comprising two source/drain regions having a channel region horizontally there-between. The channel region has opposing front and back sides along a horizontal current-flow direction through the channel region. A front gate is on the front side of the channel region. The front gate comprises part of one of a plurality of conductive vertical front access lines that individually directly electrically couple together multiple of the front gates of different ones of the ferroelectric transistors that are in different ones of the memory-cell tiers. A back gate is on the back side of the channel region. The back gate comprises part of one of a plurality of conductive vertical back lines that individually directly electrically couple together multiple of the back gates of the different ones of the ferroelectric transistors that are in different ones of the memory-cell tiers. A front-gate insulator is horizontally between the front gate and the front side of the channel region. The front-gate insulator comprises a dielectric material and a ferroelectric material and at least one of (a) and (b), where: (a): the dielectric material is directly against the front side of the channel region, the ferroelectric material is directly against the front gate, the ferroelectric material has a top that is below a top of the channel region, the ferroelectric material has a bottom that is above a bottom of the channel region, and the dielectric material extends continuously from the front side of the channel region to be both directly against the top and the bottom of the ferroelectric material; and (b): the dielectric material is directly against the front side of the channel region, the dielectric material and the ferroelectric material are each directly against the front gate, and more of the ferroelectric material is directly against the front gate than is the dielectric material.

In some embodiments, a ferroelectric transistor comprises two source/drain regions having a channel region horizontally there-between. The channel region has opposing front and back sides along a horizontal current-flow direction through the channel region. A front gate is on the front side of the channel region. A front-gate insulator is horizontally between the front gate and the front side of the channel region. The front-gate insulator comprises a dielectric material and a ferroelectric material that are each directly against the front gate. More of the ferroelectric material is directly against the front gate than is the dielectric material.

In some embodiments, memory circuitry comprises vertically-alternating insulative tiers and memory-cell tiers. The memory-cell tiers comprise memory cells that individually comprise a ferroelectric transistor comprising two source/drain regions having a channel region horizontally there-between. The channel region has opposing front and back sides along a horizontal current-flow direction through the channel region. A front gate is on the front side of the channel region. The front gate comprises part of one of a plurality of conductive vertical front access lines that individually directly electrically couple together multiple of the front gates of different ones of the ferroelectric transistors that are in different ones of the memory-cell tiers. A front-gate insulator is horizontally between the front gate and the front side of the channel region. The front-gate insulator comprises a dielectric material and a ferroelectric material that are each directly against the front gate. More of the ferroelectric material is directly against the front gate than is the dielectric material.

In some embodiments, a method used in forming memory circuitry comprising memory cells that individually comprise a horizontal ferroelectric transistor comprises forming vertically-alternating insulative tiers and memory-cell tiers. An insulator wall extends through the insulative tiers and memory-cell tiers. The insulator wall is horizontally-elongated along a first direction. Pairs of first openings extend vertically-through the insulator wall and are spaced from one another along the first direction. Individual of the first openings in individual of the pairs are spaced from one another in a second direction that is orthogonal to the first direction. Through the individual first openings, semiconductor material is laterally recessed in the second direction in individual of the memory-cell tiers selectively relative to the insulative tiers to form cavities. The semiconductor material comprises a channel region of individual horizontal ferroelectric transistors being formed. The cavities are lined with dielectric material to vertically-narrow the cavities. Ferroelectric material is formed within the vertically-narrowed cavities. After forming the ferroelectric material, a conductive front access line is formed in the individual first openings. The conductive front access line comprises a front gate on a front side of the channel region of the individual horizontal ferroelectric transistors and directly electrically couples together multiple of the front gates of different ones of the horizontal ferroelectric transistors that are in different ones of the memory-cell tiers. The dielectric and ferroelectric materials are horizontally between the front side of the channel region and the front gate.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A ferroelectric transistor comprising:
two source/drain regions having a channel region horizontally there-between, the channel region having opposing front and back sides along a horizontal current-flow direction through the channel region;
a front gate on the front side of the channel region and a back gate on the back side of the channel region;
a front-gate insulator horizontally between the front gate and the front side of the channel region; and
the front-gate insulator comprising a dielectric material and a ferroelectric material and at least one of (a) and (b), where:
(a): the dielectric material is directly against the front side of the channel region, the ferroelectric material is directly against the front gate, the ferroelectric material has a top that is below a top of the channel region, the ferroelectric material has a bottom that is above a bottom of the channel region, and the dielectric material extends continuously from the front side of the channel region to be both directly against the top and the bottom of the ferroelectric material; and
(b): the dielectric material is directly against the front side of the channel region, the dielectric material and the ferroelectric material are each directly against the front gate, and more of the ferroelectric material is directly against the front gate than is the dielectric material.

2. The ferroelectric transistor of claim 1 wherein a back-gate insulator is horizontally between the back gate and the back side of the channel region such that the back gate is not directly against the channel region.

3. The ferroelectric transistor of claim 1 wherein the back gate is directly against the back side of the channel region.

4. The ferroelectric transistor of claim 1 comprising the (a).

5. The ferroelectric transistor of claim 4 wherein the ferroelectric material is not directly against the front side of the channel region.

6. The ferroelectric transistor of claim 4 wherein the dielectric material has a C-like shape in a vertical cross-section.

7. The ferroelectric transistor of claim 4 wherein the dielectric material is directly against the front gate.

8. The ferroelectric transistor of claim 1 comprising the (b).

9. The ferroelectric transistor of claim 8 wherein the ferroelectric material is not directly against the front side of the channel region.

10. The ferroelectric transistor of claim 8 wherein the dielectric material has a C-like shape in a vertical cross-section.

11. The ferroelectric transistor of claim 1 comprising both of the (a) and the (b).

12. Memory circuitry comprising:
vertically-alternating insulative tiers and memory-cell tiers, the memory-cell tiers comprising memory cells individually comprising a ferroelectric transistor comprising two source/drain regions having a channel region horizontally there-between, the channel region having opposing front and back sides along a horizontal current-flow direction through the channel region;
a front gate on the front side of the channel region, the front gate comprising part of one of a plurality of conductive vertical front access lines that individually directly electrically couple together multiple of the front gates of different ones of the ferroelectric transistors that are in different ones of the memory-cell tiers;
a back gate on the back side of the channel region, the back gate comprising part of one of a plurality of conductive vertical back lines that individually directly electrically couple together multiple of the back gates of the different ones of the ferroelectric transistors that are in different ones of the memory-cell tiers;
a front-gate insulator horizontally between the front gate and the front side of the channel region; and
the front-gate insulator comprising a dielectric material and a ferroelectric material and at least one of (a) and (b), where:
(a): the dielectric material is directly against the front side of the channel region, the ferroelectric material is directly against the front gate, the ferroelectric material has a top that is below a top of the channel region, the ferroelectric material has a bottom that is above a bottom of the channel region, and the dielectric material extends continuously from the front side of the channel region to be both directly against the top and the bottom of the ferroelectric material; and
(b): the dielectric material is directly against the front side of the channel region, the dielectric material and the ferroelectric material are each directly against the front gate, and more of the ferroelectric material is directly against the front gate than is the dielectric material.

13. The memory circuitry of claim 12 comprising horizontal digitlines in individual of the memory-cell tiers, individual of one of the two source/drain regions of individual of the ferroelectric transistors that are in the same memory-cell tier being directly electrically coupled to one of the horizontal digitlines.

14. The memory circuitry of claim 13 wherein the one horizontal digitline is directly against a lateral-side surface of the individual one of the two source/drain regions.

15. The memory circuitry of claim 13 wherein the one horizontal digitline is directly against a top surface of the individual one of the two source/drain regions.

16. The memory circuitry of claim 13 wherein the one horizontal digitline is directly against a bottom surface of the individual one of the two source/drain regions.

17. The memory circuitry of claim 12 wherein the two source/drain regions comprise first and second source/drain regions, and further comprising:
horizontal first and second comparative digitlines in individual of the memory-cell tiers, individual of the first source/drain regions of individual of the ferroelectric transistors that are in the same memory-cell tier being directly electrically coupled to one of the horizontal first comparative digitlines, individual of the second source/drain regions of the individual ferroelectric transistors that are in the same memory-cell tier being directly electrically coupled to one of the horizontal second comparative digitlines.

18. A ferroelectric transistor comprising:
two source/drain regions having a channel region horizontally there-between, the channel region having opposing front and back sides along a horizontal current-flow direction through the channel region;
a front gate on the front side of the channel region; and
a front-gate insulator horizontally between the front gate and the front side of the channel region, the front-gate insulator comprising a dielectric material and a ferroelectric material that are each directly against the front gate, more of the ferroelectric material being directly against the front gate than is the dielectric material.

19. Memory circuitry comprising:
vertically-alternating insulative tiers and memory-cell tiers, the memory-cell tiers comprising memory cells individually comprising a ferroelectric transistor comprising two source/drain regions having a channel region horizontally there-between, the channel region having opposing front and back sides along a horizontal current-flow direction through the channel region;
a front gate on the front side of the channel region, the front gate comprising part of one of a plurality of conductive vertical front access lines that individually directly electrically couple together multiple of the front gates of different ones of the ferroelectric transistors that are in different ones of the memory-cell tiers; and
a front-gate insulator horizontally between the front gate and the front side of the channel region, the front-gate insulator comprising a dielectric material and a ferroelectric material that are each directly against the front gate, more of the ferroelectric material being directly against the front gate than is the dielectric material.

20. A method used in forming memory circuitry comprising memory cells that individually comprise a horizontal ferroelectric transistor, the method comprising:
forming vertically-alternating insulative tiers and memory-cell tiers, an insulator wall extending through the insulative tiers and memory-cell tiers, the insulator wall being horizontally-elongated along a first direction, pairs of first openings that extend vertically-through the insulator wall and are spaced from one another along the first direction, individual of the first openings in individual of the pairs being spaced from one another in a second direction that is orthogonal to the first direction;
through the individual first openings, laterally recessing semiconductor material in the second direction in individual of the memory-cell tiers selectively relative to the insulative tiers to form cavities, the semiconductor material comprising a channel region of individual horizontal ferroelectric transistors being formed;
lining the cavities with dielectric material to vertically-narrow the cavities;
forming ferroelectric material within the vertically-narrowed cavities; and
after forming the ferroelectric material, forming a conductive front access line in the individual first openings; the conductive front access line comprising a front gate on a front side of the channel region of the individual horizontal ferroelectric transistors and directly electrically coupling together multiple of the front gates of different ones of the horizontal ferroelectric transistors that are in different ones of the memory-cell tiers, the dielectric and ferroelectric materials being horizontally between the front side of the channel region and the front gate.
